(19) United States
(12) Patent Application Publication
(10) Pub. No.: US 2007/0077761 A1
(43) Pub. Date: Apr. 5, 2007

(54) TECHNIQUE FOR FORMING A COPPER-BASED METALLIZATION LAYER INCLUDING A CONDUCTIVE CAPPING LAYER

(76) Inventors: Matthias Lehr, Dresden (DE); Frank Koschinsky, Radebeul (DE); Markus Nopper, Dresden (DE)

Correspondence Address: WILLIAMS, MORGAN & AMERSON, 10333 RICHMOND, SUITE 1100, HOUSTON, TX, 77042, US

(21) Appl. No.: 11/426,346

(22) Filed: Jun. 26, 2006

(30) Foreign Application Priority Data
Sep. 30, 2005 (DE) 10 2005 046 975.2

(51) Int. Cl. H01L 21/4763

(52) U.S. Cl. 438/687; 438/637; 438/638; 257/774

(57) ABSTRACT

By providing a conductive capping layer for metal-based interconnect lines, an enhanced performance with respect to electromigration may be achieved. Moreover, a corresponding manufacturing technique is provided in which via openings may be reliably etched into the capping layer without exposing the underlying metal, such as copper-based material, thereby also providing enhanced electromigration performance, especially at the transitions between copper lines and vias.

### BACKGROUND OF THE INVENTION

1. Field of the Invention

Generally, the present invention relates to the formation of microstructures, such as advanced integrated circuits, and, more particularly, to the formation of conductive structures, such as copper-based metallization layers, and techniques to reduce their electromigration during operating and stress conditions.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area, as typically the number of interconnections required increases more rapidly than the number of circuit elements. Thus, a plurality of stacked “wiring” layers, also referred to as metallization layers, are usually provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, memory chips, ASICs (application specific ICs) and the like. The reduced cross-sectional area of the interconnect structures, possibly in combination with an increase of the static power consumption of extremely scaled transistor elements, may result in considerable current densities in the metal lines.

Advanced integrated circuits, including transistor elements having a critical dimension of 0.13 μm and even less, may, therefore, require significantly increased current densities of up to several kA per cm² in the individual interconnect structures, despite the provision of a relatively large number of metallization layers, owing to the significant number of circuit elements per unit area. Operating the interconnect structures at elevated current densities, however, may entail a plurality of problems related to stress-induced line degradation, which may finally lead to a premature failure of the integrated circuit. One prominent phenomenon in this respect is the current-induced material transportation in metal lines and vias, also referred to as “electromigration,” which may lead to the formation of voids within and hillocks next to the metal interconnect, thereby resulting in reduced performance and reliability or complete failure of the device. For instance, aluminum lines embedded into silicon dioxide and/or silicon nitride are frequently used as metal for metallization layers, wherein, as explained above, advanced integrated circuits having critical dimensions of 0.18 μm or less, may require significantly reduced cross-sectional areas of the metal lines and, thus, increased current densities, which may render aluminum less attractive for the formation of metallization layers.

Consequently, aluminum is being replaced by copper and copper alloys, a material with significantly lower resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials. To provide the necessary adhesion and to avoid the undesired diffusion of copper atoms into sensitive device regions, it is, therefore, usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitances of neighboring copper lines, which may result in non-tolerable signal propagation delays. Hence, a thin conductive barrier layer that also imparts the required mechanical stability to the copper is formed to separate the bulk copper from the surrounding dielectric material, and only a thin silicon nitride, silicon carbide or silicon carbon nitride layer in the form of a capping layer is frequently used in copper-based metallization layers. Currently, tantalum, titanium, tungsten and their compounds with nitrogen and silicon and the like are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first a dielectric layer is formed which is then patterned to include trenches and/or vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less in combination with trenches having a width ranging from 0.1 μm to several μm. Electrochemical deposition processes for copper are well established in the field of electronic circuit board fabrication. However, the void-free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may not, therefore, be significantly altered for a given microstructure, it is of great importance to estimate and control the impact of materials, such as conductive and non-conductive barrier layers, of the copper microstructure and their mutual interaction on the characteristics of the interconnect structure to insure both high yield and the required product reliability. In particular, it is important to identify, monitor and reduce degradation and failure mechanisms in interconnect structures for various configurations to maintain device reliability for every new device generation or technology node.

Accordingly, a great deal of effort has been invested in investigating the degradation of copper interconnects, especially in combination with low-k dielectric materials having a relative permittivity of 3.1 or even less, in order to find new materials and process strategies for forming copper-based lines and vias with a low overall permittivity. Although the exact mechanism of electromigration in copper lines is still not quite fully understood, it turns out that voids positioned in and on sidewalls and especially at interfaces to neighboring materials may have a significant impact on the finally achieved performance and reliability of the interconnects.

One failure mechanism, which is believed to significantly contribute to a premature device failure, is the electromigration-induced material transport, particularly along an interface formed between the copper and a dielectric capping layer acting as an etch stop layer during the formation of vias in the interlayer dielectric. Frequently used materials are, for example, silicon nitride and silicon carbon nitride, which exhibit a moderately high etch selectivity to typically employed interlayer dielectrics, such as a plurality of low-k dielectric materials, and also suppress the diffusion of copper onto the interlayer dielectric. Recent research results seem to indicate, however, that the interface formed between the copper and the etch stop layer is a major diffusion path for material transport during operation of the metal interconnect.

In view of the above-described problems, there exists a need for a technique that allows reduction of electromigration in copper-based interconnect structures without unduly increasing production costs and affecting the electrical conductivity of the metal interconnect.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of metal regions and metal lines, in particular embodiments copper-based metal lines, in metallization layers, which may, in some embodiments, include low-k dielectric materials, wherein the confinement of the metal line in the dielectric material is enhanced by providing a conductive capping layer, such as a layer comprising cobalt, tungsten and phosphorous (CoWP), a layer comprising cobalt, tungsten and boron (CoWB), a layer comprising nickel, molybdenum and boron (NiMoB) or a layer comprising nickel, molybdenum and phosphorous (NiMoP), at some interface portions between the dielectric material and the metal. In the following, a conductive capping layer may be understood as a layer including at least one metal as a major component. For example, the materials as specified above may represent suitable materials for forming a conductive capping layer. Moreover, any contacts to the metal line or metal region may be formed such that they terminate within the conductive capping layer, thereby reducing the risk of metal exposure, in particular copper exposure, during the manufacturing process for forming metallization layers in highly advanced semiconductor devices. Consequently, an enhancement with respect to stress-induced material transport phenomena in the metallization layer may be achieved due to the superior characteristics of the conductive capping layer.

According to one illustrative embodiment of the present invention, a method comprises forming a first opening in a dielectric layer stack formed above a metal region, which comprises a metal-containing portion and a conductive capping layer, wherein the conductive capping layer covers the copper-containing portion to form at least one interface with the dielectric layer stack. Moreover, the method comprises etching through the first opening into the conductive capping layer while maintaining the metal-containing portion covered. Finally, the method comprises filling the first opening at least with a barrier material and a copper-containing metal.

According to another illustrative embodiment of the present invention, a semiconductor device comprises a metal-containing region formed in a first dielectric layer and a dielectric layer stack formed above the first dielectric layer and the metal-containing region. The semiconductor device further comprises a conductive capping layer formed on the metal-containing region so as to form an interface with the dielectric layer stack. Furthermore, the semiconductor device comprises a via formed in the dielectric layer stack and filled with a conductive material comprising a metal, wherein the via terminates in the conductive capping layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1i schematically show cross-sectional views of a semiconductor device during various manufacturing stages for forming a copper-based metal region having enhanced electromigration performance in accordance with illustrative embodiments of the present invention; and

FIG. 2 schematically shows a cross sectional view of a semiconductor device during the formation of a via terminating in a conductive capping layer in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

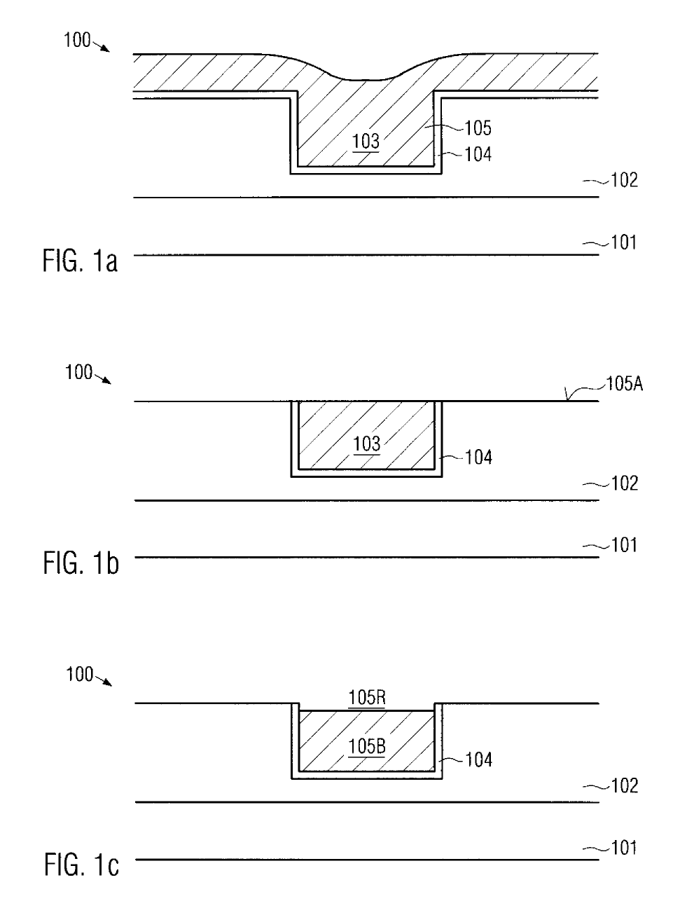

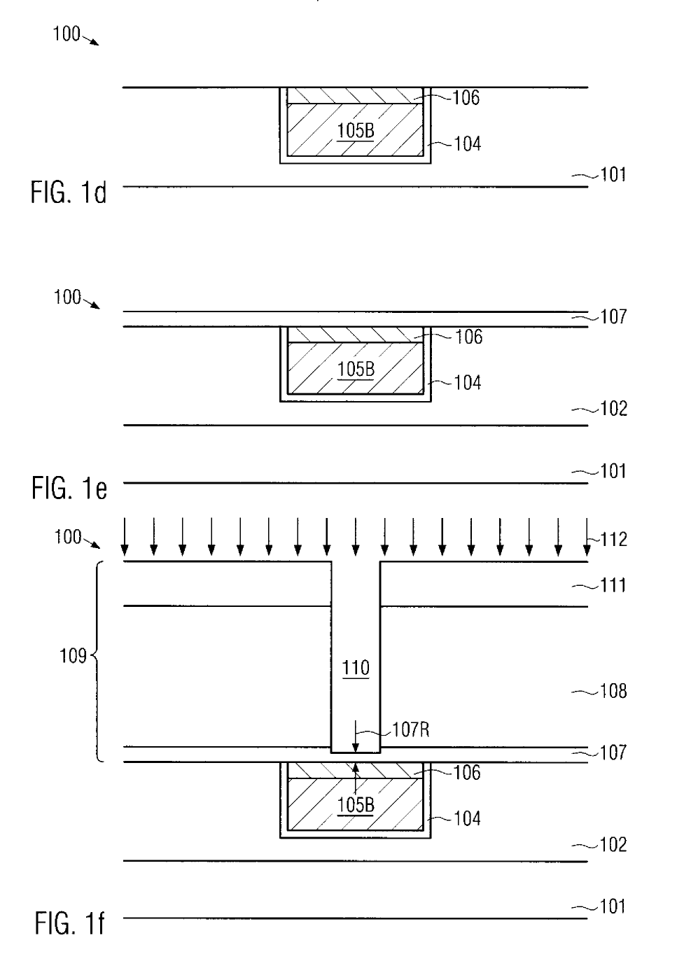

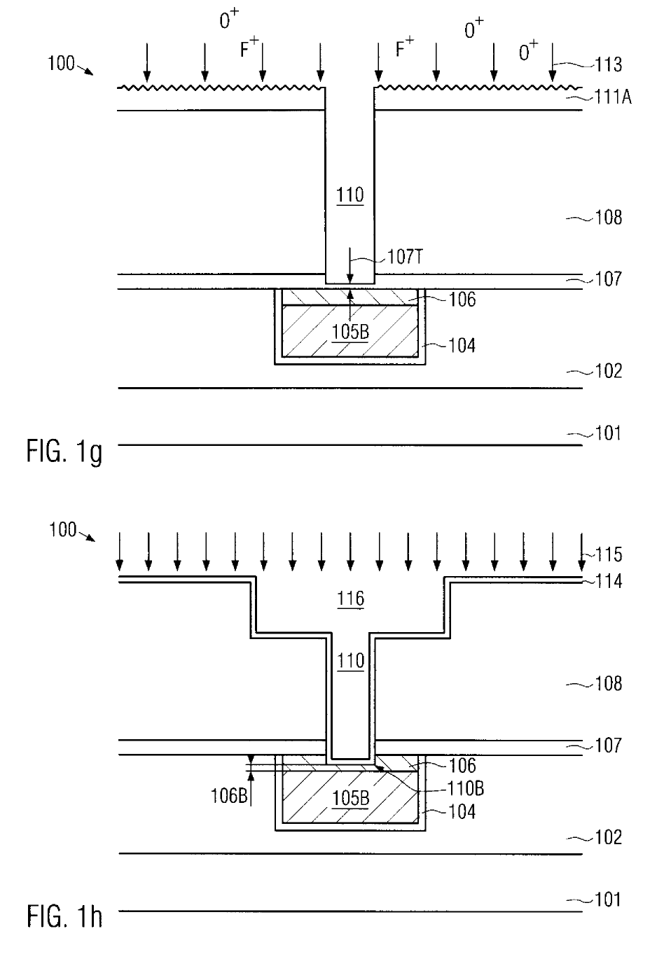

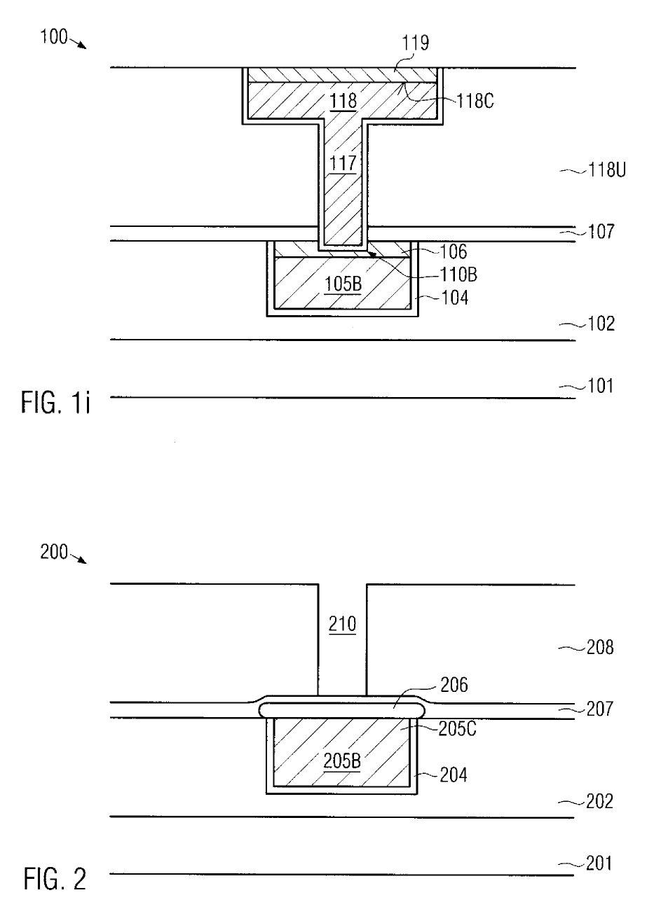

The present invention is based on the concept that in metal lines and regions, and particularly in copper-based metal lines and regions, an enhanced performance with respect to electromigration or other stress-induced metal migration phenomena may be enhanced by providing a “reinforced” interface between the metal material and the dielectric compared to conventional interfaces formed by dielectric materials, such as silicon nitride, silicon carbide, nitrogen enriched silicon carbide, and the like. For example, certain materials may result in an interface to the adjacent copper, which may significantly increase the resistance against electromigration effects, thereby extending the operational margin of devices and/or enhancing the reliability of the corresponding metallization layers. According to the present invention, a conductive capping layer that may be comprised of one or more of the materials specified above may be provided such that especially failure-prone locations in metallization layers, for instance, the transition areas between vias and metal lines, may be significantly reinforced in that the via may not extend through the conductive capping layer but reliably terminates therein, thereby ensuring a strong interface with the underlying metal, in particular embodiments the copper or copper alloy, which may not even be exposed during the entire fabrication process of the via. For this purpose, appropriately designed etch regimes may be used that allow enhanced etch control during the formation of respective via openings, wherein, in some embodiments, an etch step for opening an etch stop layer provided in the dielectric layer stack accommodating the via opening is designed so as to remove a major portion of the etch stop layer in a highly controlled fashion. Consequently, the conductive capping layer may be provided with a moderately low thickness, while nevertheless ensuring the desired superior characteristics with respect to electromigration. With reference to FIGS. 1a-1i and 2, further illustrative embodiments of the present invention will now be described in more detail.

FIG. 1a schematically illustrates a cross-sectional view of a semiconductor device 100 during a moderately advanced manufacturing stage. The semiconductor device 100 comprises a substrate 101, which may represent any substrate that is appropriate for the formation of circuit elements thereon. For instance, the substrate 101 may be a bulk semiconductor substrate, an insulating substrate having formed thereon a semiconductor layer, such as a crystalline silicon region, a silicon/germanium region, or any other III-V semiconductor compound, or II-VI compound, and the like. Typically, the substrate 101 may represent a carrier having formed thereon a large number of circuit elements, such as transistors, capacitors and the like, as are required for advanced integrated circuits. These circuit elements may be electrically connected in accordance with a specific circuit design by means of one or more metallization layers, wherein, for convenience, the formation of a single metallization layer including a single metal line or metal region will be described herein. It may, however, be readily appreciated that the concept of enhancing the electromigration or stress-induced material migration behavior by using a conductive capping layer comprised of one or more of the above-identified materials may be applied to any complex device configuration including a plurality of metallization layers and a plurality of interconnect lines and vias. In illustrative embodiments, the metal regions or lines may be a copper-based metal line and regions, which may, in particular embodiments, be formed in a low-k dielectric material. Moreover, although the present invention is particularly advantageous for extremely scaled semiconductor devices, since here, as previously discussed, moderately high current densities are usually encountered during the operation of the device, the present invention may also be readily applicable and advantageous for moderately scaled devices, due to a significantly enhanced reliability and lifetime that may be obtained by further reducing stress-induced metal migration phenomena, such as electromigration.

The semiconductor device 100 may comprise a dielectric layer 102, which may represent the dielectric material of a metallization layer, or any other interlayer dielectric material and the like. In highly advanced semiconductor devices, the dielectric layer 102 may comprise a low-k dielectric material so as to reduce the parasitic capacitance between neighboring metal lines. In this respect, a low-k dielectric material is to be understood as a dielectric having a relative permittivity that is less than approximately 3.0 and hence exhibits a significantly smaller permittivity than, for instance, well-established “conventional” dielectrics, such as silicon dioxide, silicon nitride and the like. A trench 103 is formed in the dielectric layer 102 and may be filled with a conductive material comprising a barrier layer 104 and a metal 105, which in particular embodiments may be a copper-containing metal, which may be provided in excess so as to reliably fill the trench 103.

A typical process flow for forming the semiconductor device 100 as shown in FIG. 1a may comprise the following processes. After any well-established process techniques for forming any circuit elements and microstructural elements in and on the substrate 101, the dielectric layer 102 may be formed, which may comprise two or more sub-layers, depending on device requirements. For example, the dielectric layer 102 may be formed on the basis of well-established plasma enhanced chemical vapor deposition (PECVD) techniques, when comprising silicon dioxide, silicon nitride and the like. However, other deposition techniques may be used, such as spin-on techniques for any low-k polymer materials and the like. Thereafter, an appropriately designed photolithography process may be performed to provide an appropriate resist mask (not shown), which may be used to pattern the trench 103 on the basis of well-established anisotropic etch techniques.

Next, the barrier layer 104 may be formed by any appropriate deposition technique, such as sputter deposition, chemical vapor deposition, atomic layer deposition and the like. For instance, the barrier layer 104 may be comprised of conductive materials, such as tantalum, tantalum nitride, titanium, titanium nitride, tungsten, tungsten nitride, or any other appropriate material, wherein, in some embodiments, two or more different material compositions and layers may be provided, as is required for achieving the desired adhesion and diffusion blocking characteristics. In one illustrative embodiment, the barrier layer 104 is comprised of one or more of CoWP, CoWB, NiMoB and NiMoP, at least as an uppermost layer, if the barrier layer 104 is provided in the form of a layer stack. For example, the barrier layer 104 may be deposited on the basis of an electrochemical deposition process so as to form a conductive capping layer, wherein an appropriate catalyst material may be deposited prior to the actual formation of the barrier layer 104. For instance, palladium may act as a catalyst material for initiating the deposition of the conductive capping layer in an electroless plating process, wherein, after an initial deposition of the material, such as CoWP, the subsequent deposition process is auto catalyzed by the previously deposited material. In other embodiments, a first barrier layer may be deposited, which may comprise an appropriate catalyst material, such as palladium, for instance by sputter deposition and the like, and subsequently an electrochemical deposition of the conductive capping layer may follow.

After the deposition of the barrier layer 104, in some embodiments, a copper seed layer may be deposited by any appropriate deposition technique, such as sputter deposition, electroless deposition and the like, if a copper-based material is to be filled in on the basis of well-established electroplating techniques. In other embodiments, the provision of a seed layer may not be required. Corresponding recipes for forming a seed layer are well-established in the art. Thereafter, the metal material 105, for example in the form of a copper-containing metal, may be deposited on the basis of well-established techniques, such as electroplating, electroless plating and the like, wherein typically a certain amount of excess material is provided to ensure a reliable filling of the trench 103.

FIG. 1b schematically shows the semiconductor device 100 in a further advanced manufacturing stage. In the embodiment shown, the excess material of the metal layer 105 and the barrier layer 104 is removed to provide a substantially planarized surface topology, which is indicated as 105A. The removal of excess material of the layer 105 and the barrier layer 104 may be accomplished by chemical mechanical polishing (CMP) and/or electrochemical polishing on the basis of well-established recipes. For example, the layer 105 as shown in FIG. 1a may be treated by CMP so as to provide a substantially planarized surface topology 105A, and subsequently an electrochemical etch process may be performed for removing the residual excess material and to form a recess in the trench 103. In other embodiments, the chemical mechanical polishing process resulting in the planarized surface topology 105A may be continued and may be performed with a specific over-polish time so as to form a desired recess in the trench 103. For this purpose, process parameters and the CMP tool configuration may be selected such that a corresponding “dishing” effect is achieved. For example, the down force and/or, the relative speed between polishing pad and substrate, and/or the configuration of the slurry and polishing pad may be appropriately selected to result in a substantially uniform recessing of the trench 103.

FIG. 1c schematically shows the semiconductor device 100 after the completion of the above-described process sequence. Hence, the device 100 comprises the trench 103 filled with a metal portion, which is now indicated as 105B, and also comprises a recess 105R. Moreover, depending on the process strategy, the barrier layer 104 may still be in place with a more or less reduced thickness on horizontal portions, depending on the preceding processes for forming the recess 105R. In other embodiments, in the previous removal process, the barrier layer 104 may be removed from horizontal portions by CMP or any other removal techniques, such as selective etching and the like. In one illustrative embodiment (not shown), the barrier layer 104 may be substantially maintained and may comprise a catalyst material, such as palladium, to enable a subsequent electrochemical deposition of a conductive material, such as CoWP, CoWB, NiMoP, NiMoB. In other embodiments, as previously explained, the barrier layer 104 may be comprised, at least partially, of one or more of CoWP, CoWB, NiMoP, NiMoB and hence an auto catalytic deposition of this material may be obtained. In this case, a layer of these materials may also be grown within the recess 105R, since a lateral growth of the material may also occur. In still other embodiments, a corresponding catalyst material may be deposited prior to the subsequent electrochemical deposition of the conductive capping material, wherein, in some embodiments, the catalyst material may be provided in a highly selective manner, for instance by selectively depositing the catalyst material on the metal-based material 105 in an electroless plating process. In this case, the conductive capping material may be substantially deposited within the recess 105R only. In still other embodiments, an appropriate catalyst material may have been included during the deposition of the metal-based material, at least at a certain deposition phase, so that at least a surface portion of the metal-based portion 105B may include the catalyst material. Consequently, also in this case, a highly selective deposition of the conductive capping layer material may be achieved in the subsequent electrochemical deposition process. For example, in one illustrative embodiment, copper-based metal may have been deposited as the metal 105 in an electrochemical deposition process, in which an appropriate catalyst material may be added to the plating solution, permanently or temporarily at a final phase, so that at least a central portion of the copper-based portion 105b may comprise the catalyst material, which may then also serve as a “growth center” for a further capping layer material deposition.

FIG. 1d schematically shows the semiconductor device 100 after the completion of the electrochemical deposition process for selectively forming, in one illustrative embodiment, a conductive capping layer comprised of one or more of CoWP, CoWB, NiMoP, NiMoB 106, thereby filling the recess 105R. Consequently, the metal-containing portion 105B forms an interface 105C with the conductive capping layer 106, thereby significantly enhancing the characteristics of the interface 105C with respect to its electromigration behavior. Thereafter, any excess material of the layer 106, if provided, may be removed and the surface topography of the device 100 may be planarized on the basis of well-established techniques, such as chemical mechanical polishing, electrochemical etching, and the like, if necessary.

FIG. 1e schematically shows the semiconductor device 100 after the completion of the above-described process sequence and with an etch stop layer 107 formed on the dielectric layer 102 and the layer 106. The etch stop layer 107, which may represent a first portion of a dielectric layer stack still to be formed, may be comprised of any appropriate material, such as silicon nitride, silicon carbide, nitrogen enriched silicon carbide, and the like. The layer 107 may be formed on the basis of well-established process techniques, such as PECVD and the like. Thereafter, a further dielectric material may be deposited on the etch stop layer 107 in accordance with device requirements. In illustrative embodiments, for example, in highly advanced semiconductor devices, a low-k dielectric material, such as SiCOH, or polymer materials and the like, may be formed above the etch stop layer 107 in any appropriate configuration. For instance, two or more different dielectric materials, partly in the form of a low-k material and partly in the form of “conventional” dielectrics, such as fluorine-doped silicon dioxide and the like, may be used. It should be appreciated that the dielectric layer to be formed on the etch stop layer 107 and its configuration may also depend on the manufacturing strategy used. For example, in a so-called dual damascene technique, the dielectric layer to be formed on the etch stop layer 107 may be designed such that it accommodates metal lines and vias, wherein the corresponding via openings and trench openings may be formed in a specified sequence, wherein the vias may be formed first and subsequently the trenches may be formed, while in other strategies, the trenches may be formed first and subsequently the vias may be fabricated. In still other strategies, so-called single damascene techniques, the dielectric layer to be formed on the etch stop layer 107 may be designed to receive corresponding vias and subsequently a further dielectric layer may be formed in which corresponding trenches are to be patterned. Without intending to restrict the present invention to any specific manufacturing strategy unless set forth in the appended claims, in the following it is referred to a so-called via-first-trench-last approach, wherein it is to be appreciated that any other sequence may be used as well.

FIG. 1f schematically shows the device 100 in a further advanced manufacturing stage, wherein the device 100 comprises a dielectric layer stack 109 including the etch stop layer 107 and a further dielectric layer 108, which, as previously discussed, may be comprised of two or more individual dielectric layers. Moreover, a resist mask 111 is formed above the dielectric layer stack 109 and a via opening 110 is formed in the dielectric layer 108 and extends into the etch stop layer 107.

The dielectric layer 108 may have been formed in accordance with the process techniques described above and the resist mask 111 may be formed on the basis of well-established photolithography techniques. Thereafter, an anisotropic etch process 112 may be performed on the basis of well-known etch recipes to etch through the dielectric layer 108, wherein the etch process may stop on and in the etch stop layer 107. For instance, well-known recipes including fluorine and carbon or fluorine, carbon and hydrogen compounds may be used wherein, in some illustrative embodiments, the etch process 112 may be stopped upon reaching the etch stop layer 107 or after removal of only a minor portion thereof, as is indicated by a residual thickness 107R of the etch stop layer 107. Hence, in some illustrative embodiments, the etch process 112 may be performed such that only a minor amount of approximately 0-30% of the initial layer thickness of the etch stop layer is removed. A corresponding controlled end of the etch process 112 may be accomplished on the basis of endpoint detection, which optically detects specific volatile components in the etch ambient, when the material of the etch stop layer 107 is increasingly removed. It should be appreciated that, in these embodiments, pronounced etching of the etch stop layer 107, as may be performed on the basis of conventional etch recipes, which may also be used in other illustrative embodiments, may be avoided to reduce etch non-uniformities, since a further highly controllable etch step designed to remove the resist mask 111 and adjust a thickness of the residual material of the etch stop layer 107 in a highly controlled manner may be performed afterwards, as will be described with reference to FIG. 1g. Thus, in these embodiments, the etch process 112 may be stopped on the basis of process requirements with respect to the process 112, without necessitating any extended over-etch times provided in other techniques as a compromise between reliable material removal of the layer 108, etch stop layer reduction and avoiding damage of the underlying material, as is typically the case in conventional strategies for forming copper-based metallization layers without the capping layer 106. In other embodiments, enhanced process control during the formation of the via opening 110 and the subsequent reduction of the thickness 107R may not be considered necessary, and thus conventional process strategies may be used.

During the etch process 112, any volatile by-products may form fluorine-containing polymers, which may deposit on process chamber surfaces of the respective etch tool, the back side of the substrate 101, whereas this polymer material may not substantially deposit on the resist mask 111 due to the on-going particle bombardment caused by the plasma-based etch process 112. Consequently, in one illustrative embodiment, a source of fluorine is available for a subsequent highly controlled etch process to reduce the thickness 107R of the etch stop layer 107 and also remove the resist mask 111.

FIG. 1g schematically shows the semiconductor device 100 during a subsequent etch process 113 designed to reduce the thickness of the etch stop layer 107 to a specified target value in a highly controllable manner. In one particular embodiment, the etch process 113 is designed to remove the resist mask 111, wherein an intermediate stage is shown in which a substantial portion of the resist mask is already removed, while a remaining portion 111A is still present. Thus, in one particular embodiment, the substrate 101 may be kept in the same process chamber as previously used for the etch process 112 so that exposed chamber surfaces may have formed thereon the fluorine-containing polymer material previously deposited. Moreover, the etch process 113 may comprise a plasma ambient on the basis of oxygen, which is typically used for resist ashing. During the etch process 113, the polymer material deposited is also attacked and dissolved, thereby liberating fluorine which then enters the plasma ambient of the process 113 and is now available for the removal of material of the etch stop layer 107. In other illustrative embodiments, the fluorine may be supplied by an external source so as to establish the desired etch ambient for removing the resist mask 111 and etching the etch stop layer 107. Consequently, during the removal of the resist mask 111, the residual thickness 107R (FIG. 1f) may also be reduced in a highly controllable manner such that a high across-substrate uniformity of the etch process 113 and thus of a target thickness 107T may be achieved, thereby providing the conductive capping layer 106 with a reduced thickness, since etching the etch stop layer 107 is highly uniform, thereby reducing the risk for etching through the capping layer 106 in a final etch process for opening the etch stop layer by removing the target thickness 107T and etching into the capping layer 106. It should be appreciated that, in other illustrative embodiments, the etch process 113 for removing the resist mask 111 and etching into the etch stop layer 107 and into the capping layer 106 may comprise separate steps.

Next, according to the via-first-trench-last approach, a further lithography and etch sequence may be performed on the basis of well-established recipes to form a trench in an upper portion of the dielectric layer stack 109. Finally, the etch stop layer 107 may be opened, wherein, as explained above, in some embodiments, the highly uniform and reduced target thickness 107T may provide enhanced etch control so that the etch stop layer material may be reliably removed and it may be etched into the capping layer 106 without exposing the underlying metal portion 105B.

FIG. 1h schematically shows the semiconductor device 100 after completion of the etch process 113 and the above-described sequence for forming a trench above the via opening 110 and opening the etch stop layer 107. The device 100 now comprises the via opening 110 extending into the capping layer 106, wherein, however, the remaining thickness 106B is provided to avoid exposure of the underlying metal-containing portion 105B. For example, the thickness 106B may range from approximately 5-30 nm, thereby keeping the resulting via resistivity at a moderately low level. Moreover, a trench 116 is formed to connect to the via opening 110. Furthermore, a barrier layer 114 is formed on exposed surfaces of the trench 116 and the via opening 110, wherein the barrier layer 114 may be comprised of any appropriate material as is also explained with reference to the barrier layer 104.

The barrier layer 114 may be formed by any appropriate deposition technique, such as CVD, PVD, electrochemical deposition, atomic layer deposition and the like. In one illustrative embodiment, the barrier layer 114 may be formed by a sputter deposition process 115, wherein a preceding sputter clean process, which is usually performed prior to depositing the barrier material on a copper-based metal region, due to the increased tendency of copper to form oxidized portions, may not be necessary or may be performed with reduced intensity due to the provision of the capping layer 106, thereby reducing the risk for undue material erosion of the exposed capping layer 106. Moreover, in some illustrative embodiments, after the deposition of the barrier layer 114, an appropriately designed re-sputtering process may be performed to substantially completely remove the material of the barrier layer 114 from a bottom 110B of the via opening 110. Consequently, the thickness 106B may then substantially determine the resulting contact resistance from the via 110 to the metal-containing portion 105B, since any contribution of the barrier layer 114 may be significantly reduced. In other embodiments, the barrier layer 114 may also be provided on the bottom 110B in accordance with established via formation techniques. Thereafter, an appropriate copper seed layer may be formed in embodiments in which a copper-based material is to be formed within the via. Subsequently, the trench 116 and the via opening 110 may be filled with a metal, such as a copper-based material, on the basis of well-established deposition recipes, such as electrochemical deposition techniques. After the deposition of the metal material, a similar process sequence may be performed as is previously described with reference to FIGS. 1a-1e, in which is described the formation of the metal-based portion 105B including the capping layer 106.

FIG. 1i schematically shows the semiconductor device 100 after the completion of the above-specified process sequence. Hence, the semiconductor device 100 comprises a via 117 and a metal line 118 formed in an upper portion 118U of the dielectric layer 108. Moreover, in one embodiment, a capping layer 119 comprised of one or more of the materials as are specified above for the layer 106 may be formed on the metal line 118, thereby forming an interface 118C having an enhanced resistance against electromigration.

As a result, the semiconductor device 100 comprises an enhanced interconnect structure, which may include copper-based metals that may in advanced applications be formed within low-k dielectric materials, wherein a significantly enhanced performance with respect to electromigration or other stress-induced material migration effects may be achieved due to the presence of one or more capping layers 119 and 106, wherein any via terminates within the layer 106 without exposing the underlying metal.

In the embodiments described with reference to FIGS. 1a-1i, the capping layers 119 and 106 are formed within recesses in the underlying metal portion. However, other techniques may be used, as will be described with reference to FIG. 2, for exemplary embodiments of the present invention.

FIG. 2 schematically shows a semiconductor device 200 comprising a substrate 201 and a dielectric layer 202 formed thereabove, which may include a metal region 205B, such as a copper-based region, separated from the dielectric layer material 202 by an appropriate barrier layer 204. Regarding the characteristics of the various components 201, 202, 205B and 204, it is referred to the corresponding components as previously described with reference to FIGS. 1a-1d. Moreover, the semiconductor device 200 comprises a conductive capping layer 206 comprised of one or more of the materials as specified above for the layers 106 and 119, which is formed above the metal region 205B and the dielectric layer 202. Moreover, in some illustrative embodiments, an etch stop layer 207 may be provided, followed by a dielectric layer 208, in which may be formed a via opening 210.

In one illustrative embodiment, the capping layer 206 may be formed in a substantially self-aligned manner by providing a catalyst material at least on top of the metal region 205B or a portion thereof, depending on the process strategy, as indicated by 205C, wherein the catalyst material 205C may be provided during the deposition of the copper-based material for forming the metal region 205B, as is also previously explained, or wherein the catalyst material 205C may be deposited in a selective manner, for instance by electroless selective deposition, after a process sequence as previously explained with reference to FIGS. 1a-1d. Consequently, any processes for recessing the copper region 205B may be omitted and the capping layer 206 may “grow” in a self-aligned fashion, thereby significantly reducing process complexity. Subsequently, the etch stop layer 207 may be formed according to well-established process recipes and the subsequent processing for forming the dielectric layer 208 and etching the via opening 210 may be performed in a similar fashion as previously described with reference to the components 108 and 110. Thereafter, the further processing may be performed as is previously described.

As a result, the present invention provides an enhanced technique for the formation of metallization layers, in particular embodiments copper-based metallization layers, in which enhanced electromigration performance may be achieved, wherein particularly failure-prone portions, such as transition regions between vias and copper-based metal lines, may receive a highly efficient conductive capping layer comprised of materials, such as CoWP, CoWB, NiMoP and NiMoB, which may be reliably maintained throughout the entire manufacturing process. A thickness of the capping layer may be selected in accordance with device requirements, wherein, in some particular embodiments, a highly efficient etch strategy may be used, which may provide a precise opening of the etch stop layer and etching into the capping layer without exposing the underlying copper-based metal. Hence, the required layer thickness of the capping layer with respect to process margins may be selected moderately thin so as to not unduly affect the electrical resistance of the corresponding via.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first opening in a dielectric layer stack formed above a metal region, said metal region comprising a metal-containing portion and a conductive capping layer, said capping layer covering said metal-containing portion so as to form at least one interface with said dielectric layer stack;
etching through said first opening into said capping layer while maintaining said metal-containing portion covered by said conductive capping layer; and
filling said first opening at least with a barrier material and a metal-containing material.

2. The method of claim 1, wherein said metal comprises copper.

3. The method of claim 1, further comprising forming said metal region by:
forming a second opening in a dielectric layer;
forming a conductive barrier layer at a bottom and sidewalls of said second opening;
filling said second opening with a metal to form said metal-containing portion; and
forming said capping layer on said metal-containing portion.

4. The method of claim 3, wherein filling said second opening comprises recessing said metal to form said metal-containing portion.

5. The method of claim 4, wherein recessing said metal comprises depositing said metal in excess to overfill said second opening and removing excess material by at least one of chemical mechanical polishing and an electrochemical removal process.

6. The method of claim 1, wherein forming said capping layer comprises depositing said capping layer by an electrochemical deposition process.

7. The method of claim 6, wherein forming said capping layer comprises forming a catalyst material at least on said metal-containing portion for initiating said electrochemical deposition process.

8. The method of claim 7, further comprising removing excess material of said capping layer by at least one of chemical mechanical polishing and an electrochemical removal process.

9. The method of claim 1, wherein forming said first opening comprises etching a first portion of said opening in an upper portion of said dielectric layer stack on the basis of a first etch process, said first portion of said first opening extending into an etch stop layer provided in said dielectric layer stack and located adjacent to said capping layer.

10. The method of claim 9, further comprising etching into said etch stop layer on the basis of a second etch process comprising an oxygen plasma and fluorine.

11. The method of claim 10, wherein approximately 70% or more of a thickness of said etch stop layer is removed during said second etch process.

12. The method of claim 1, wherein filling said first opening with at least a barrier material and a metal comprises depositing said barrier material and removing material from a bottom of said first opening by performing a re-sputtering process.

13. The method of claim 12, wherein said barrier material is substantially completely removed from the bottom of said first opening.

14. The method of claim 1, further comprising forming a trench in an upper portion of said dielectric layer stack, said trench connecting to said first opening.

15. The method of claim 14, wherein said trench is formed prior to filling said first opening.

16. The method of claim 15, further comprising forming a second conductive capping layer on said trench after filling said first opening and said trench in a common process.

17. The method of claim 1, wherein said conductive capping layer is comprised of at least one compound of the following compounds: cobalt, tungsten and phosphorous (CoWP); cobalt, tungsten and boron (CoWB); nickel, molybdenum and boron (NiMoB); and nickel, molybdenum and phosphorous (NiMoP).

18. The method of claim 16 wherein said second conductive capping layer is comprised of at least one compound of the following compounds: cobalt, tungsten and phosphorous (CoWP); cobalt, tungsten and boron (CoWB); nickel, molybdenum and boron (NiMoB); and nickel, molybdenum and phosphorous (NiMoP).

19. A semiconductor device, comprising:
a metal region formed in a first dielectric layer;
a dielectric layer stack formed above said first dielectric layer and said metal region;
a conductive capping layer formed on said metal region and forming an interface with said dielectric layer stack; and
a via formed in said dielectric layer stack and filled with a conductive material, said via terminating in said conductive capping layer.

20. The semiconductor device of claim 19, wherein said conductive capping layer is comprised of at least one compound of the following compounds: cobalt, tungsten and phosphorous (CoWP); cobalt, tungsten and boron (CoWB); nickel, molybdenum and boron (NiMoB); and nickel, molybdenum and phosphorous (NiMoP).
